(19) United States
(12) Patent Application Publication
(10) Pub. No.: US 2025/0236988 A1
(43) Pub. Date: Jul. 24, 2025

(54) METHOD FOR MANUFACTURING NITRIDE STACK AND NITRIDE STACK

(71) Applicant: SUMITOMO CHEMICAL COMPANY, LIMITED, Tokyo (JP)

(72) Inventors: Shota KANEKI, Hitachi-shi (JP); Hajime Fujikura, Hitachi-shi (JP); Masafumi Yokoyama, Hitachi-shi (JP); Yoshinobu Narita, Hitachi-shi (JP)

(73) Assignee: SUMITOMO CHEMICAL COMPANY, LIMITED, Tokyo (JP)

(21) Appl. No.: 19/027,940

(22) Filed: Jan. 17, 2025

(30) Foreign Application Priority Data
Jan. 19, 2024 (JP) 2024-006654

(51) Int. Cl. C30B 25/18; C30B 29/40; H01L 21/02; H10D 30/47; H10D 30/62; H10D 62/85

(52) U.S. Cl. CPC C30B 25/186; C30B 29/403; C30B 29/406; H01L 21/02389; H01L 21/0254; H10D 62/8503; H10D 30/471; H10D 30/62

(57) ABSTRACT

There is provided a method for manufacturing a nitride stack, including: (a) preparing a substrate having at least a surface layer portion composed of a first group III nitride, the substrate being unloaded from a depositing apparatus in which the first group III nitride has been grown; (b) subjecting the substrate to a predetermined oxidation treatment using an oxidation treatment device to convert an outermost layer of the first group III nitride into a protective layer composed of a group III oxide; (c) loading the substrate into a predetermined processing chamber and heating the substrate in a reducing atmosphere to remove the protective layer from a surface of the substrate; and (d) growing a second group III nitride on a surface of the first group III nitride exposed by removing the protective layer, without unloading the substrate from the processing chamber.

### TECHNICAL FIELD

The present disclosure relates to a method for manufacturing a nitride stack and a nitride stack.

### DESCRIPTION OF RELATED ART

Group III nitride such as gallium nitride (GaN) is used as a material for manufacturing semiconductor devices such as light emitting devices and transistors. Attention is paid to a nitride stack in which a GaN layer is epitaxially grown on a GaN substrate because the GaN layer is of high quality (see for example Non-Patent Document 1, for the use of GaN substrates for growing a high-quality GaN layer).

When the GaN layer is grown on the GaN substrate, the GaN substrate is loaded from outside into a processing chamber of a depositing apparatus in which the GaN layer is grown. Then, the GaN layer is grown on the GaN substrate. That is, the GaN layer is regrown on the GaN substrate in a non-continuous manner.

Typically, as in the case of growing the GaN layer on the GaN substrate, a second group III nitride may be regrown in a non-continuous manner on a first group III nitride serving as a growth base. In this case, impurities are adhered to the surface of the first group III nitride due to the first group III nitride being unloaded to outside of the depositing apparatus after the growth of the first group III nitride. The adhered impurities adversely affect the growth of the second group III nitride, etc.

[Non-Patent Document 1] Prologue “Development of GaN Single Crystal Substrates,” Sumitomo Chemical, 2018, pp. 38 to 47 by Fujikura, et al.

### SUMMARY OF THE INVENTION

One object of the present disclosure is to provide a technique for reducing an adverse effect of impurities adhered to the surface of a first group III nitride when a second group III nitride is regrown on the first group III nitride in a non-continuous manner.

According to one aspect of the present disclosure, there is provided a method for manufacturing a nitride stack, the method including:
(a) preparing a substrate having at least a surface layer portion composed of a first group III nitride, the substrate being unloaded from a depositing apparatus in which the first group III nitride has been grown;
(b) subjecting the substrate to a predetermined oxidation treatment using an oxidation treatment device to convert an outermost layer of the first group III nitride into a protective layer composed of a group III oxide;
(c) loading the substrate into a predetermined processing chamber and heating the substrate in a reducing atmosphere to remove the protective layer from a surface of the substrate; and
(d) growing a second group III nitride on a surface of the first group III nitride exposed by removing the protective layer, without unloading the substrate from the processing chamber.

According to another aspect of the present disclosure, there is provided a nitride stack including:
a substrate having at least a surface layer portion composed of a first group III nitride; and
a protective layer composed of a group III oxide provided on a surface of the first group III nitride.

According to further another aspect of the present disclosure, there is provided a nitride stack including:
a substrate having at least a surface layer portion composed of a first group III nitride; and
a film composed of a second group III nitride provided on a surface of the first group III nitride,
wherein a concentration distribution of iron (Fe) at an interface between the first group III nitride and the second group III nitride has a peak at the interface, and a concentration of the peak is 2×10¹⁶/cm³ or less.

There is provided a technique for reducing an adverse effect of impurities adhered to the surface of a first group III nitride, when a second group III nitride is regrown on the first group III nitride in a non-continuous manner.

### BRIEF DESCRIPTION OF THE DRAWINGS

FIG. 1A is a schematic view showing a step of preparing a substrate 11 in a state where the substrate 11 is unloaded to outside of a depositing apparatus according to an embodiment of the present disclosure, and FIG. 1B is a schematic view showing a step of forming a protective layer 15 on the substrate 11 according to the embodiment.

FIG. 2A is a schematic view showing a step of removing the protective layer 15 from the substrate 11 according to an embodiment, and FIG. 2B is a schematic view showing a step of growing a film 21 on the substrate 11 according to an embodiment.

FIG. 3 is an example of a SIMS profile of a sample according to an embodiment, showing the concentration distribution of Fe, Mg, and Cr.

FIG. 4 is an example of a SIMS profile of a sample of a first comparative embodiment, showing the concentration distribution of Fe, Mg, and Cr.

FIG. 5 is an example of a SIMS profile of the sample of a second comparative embodiment, showing the concentration distribution of Fe, Mg, and Cr.

FIG. 6A and 6B are a first example and a second example, respectively, of the first group III nitride having a surface 13a with an uneven structure.

FIG. 7 is an example of a SIMS profile in a conventional nitride stack, showing the concentration distribution of Fe, Mg, and Si.

### DETAILED DESCRIPTION OF THE INVENTION

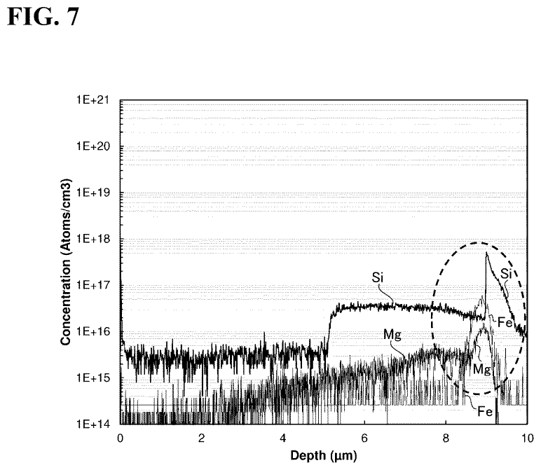

Hereinafter, a nitride stack and a method for manufacturing the same according to an embodiment of the present disclosure will be described. First, as a preliminary knowledge, a conventional nitride stack will be described. FIG. 7 is an example of a secondary ion mass spectrometry (SIMS) profile showing the concentration distribution of impurities such as iron (Fe) in a conventional nitride stack in a thickness direction, and shows the concentration distribution of Fe, magnesium (Mg), and silicon (Si).

The sample shown in FIG. 7 is a nitride stack in which a GaN layer has been epitaxially grown on a gallium nitride (GaN) substrate, that is, a nitride stack in which GaN constituting a GaN layer is regrown on GaN constituting the GaN substrate. Each of the GaN substrate and GaN layer in this example contains Si intentionally added as an n-type impurity.

The GaN substrate is loaded from outside of a processing chamber into a processing chamber of a depositing apparatus in which the GaN layer is grown. That is, before being loaded into the processing chamber, the GaN substrate is prepared in a state where it is unloaded to outside of the depositing apparatus in which GaN constituting the GaN substrate has been grown. This causes the surface of the GaN substrate to be contaminated, with various impurities such as Fe adhering to the surface of the GaN substrate. In a conventional technique of manufacturing a nitride stack, the GaN layer is grown without sufficient removal of impurities adhering to the surface of the GaN substrate.

In FIG. 7, the area surrounded by the dashed ellipse indicates a portion near the stacking interface between the GaN substrate and the GaN layer. A protrusion in the impurity concentration distribution is observed near the stacking interface, indicating the presence of Fe and Mg adhered to the GaN substrate. Further, in the Si concentration distribution also, the protrusion indicating a bias in the distribution is observed near the stacking interface. Si may be present not only as an added impurity, but also as an impurity adhered by contamination.

The impurities that adhere to the surface of the GaN substrate adversely affect the quality of the crystal that is regrown thereon. When epitaxial growth is resumed on the surface contaminated with impurities, crystallinity cannot be restored unless somewhat thick growth (e.g., 4 μm or more) is carried out.

Further, the protrusion in the distribution concentration of the impurities near the stacking interface may deteriorate device characteristics. For example, the inclusion of Fe or Mg increases the resistance of the group III nitride. Therefore, the protrusion of the Fe concentration distribution or the protrusion of the Mg concentration distribution becomes an unintentionally formed high resistance layer, which becomes a factor that inhibits a current flowing in the thickness direction in, for example, a vertical device. Further, for example, the inclusion of Si reduces the resistance of the group III nitride. Therefore, the protrusion of the Si concentration distribution becomes an unintentionally formed low resistance layer, which causes an increase in leakage current in, for example, a lateral device.

In the example shown in FIG. 7, a GaN layer with a high Si concentration (highly Si doped layer) is formed on the GaN substrate to compensate for high resistance caused by Fe, etc., and then a GaN layer with a low Si concentration used for device operation is formed. The impurity contamination also causes the time and effort to form a highly doped Si layer.

As described above, it is preferable to suppress the formation of the protrusion in the impurity concentration distribution near the stacking interface of the nitride stack. This embodiment shows a technique for manufacturing a nitride stack capable of suppressing such a protrusion in the impurity concentration distribution.

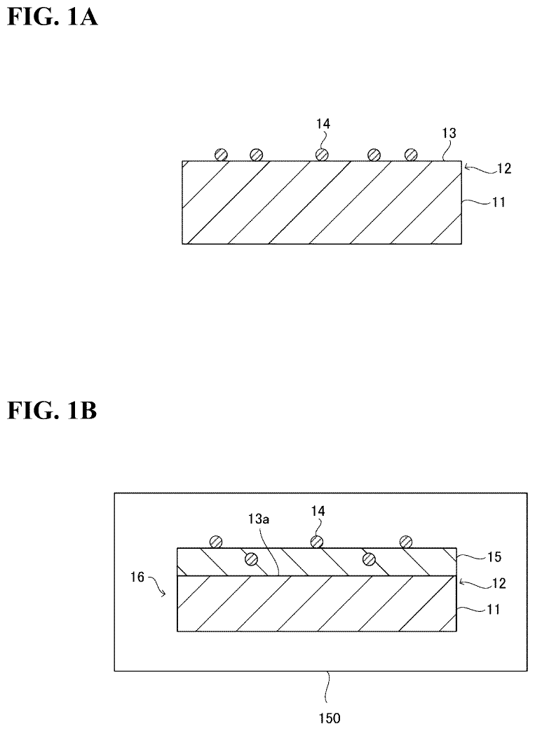

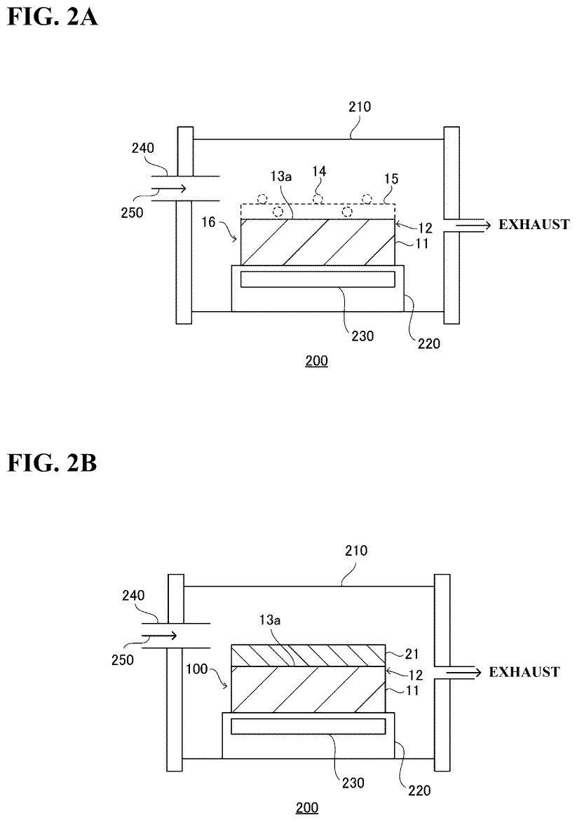

A method for manufacturing a nitride stack 100 according to an embodiment will be described with reference to FIGS. 1A to 2B. As shown in FIG. 2B, the nitride stack 100 includes a substrate 11 and a film 21. At least a surface layer portion 12 (a portion serving as a base for growth of the film 21) of the substrate 11 is composed of a group III nitride. The group III nitride constituting at least the surface layer portion 12 of the substrate 11 is referred to as a first group III nitride. The film 21 is composed of a group III nitride. The group III nitride constituting the film 21 is referred to as a second group III nitride.

FIG. 1A is a schematic view showing a step of preparing the substrate 11 in a state where the substrate 11 is unloaded to outside of a depositing apparatus in which the group III nitride (first group III nitride) constituting the surface layer portion 12 has been grown. As described above, the substrate 11 is a substrate in which at least the surface layer portion 12 is composed of the first group III nitride. The substrate 11 may be, for example, a free-standing substrate whose entire thickness is composed of the first group III nitride, or may be, for example, a stacked substrate in which a film composed of the first group III nitride is provided on a base substrate.

The phrase “the substrate 11 is prepared in a state where it is unloaded to outside of the depositing apparatus in which the first group III nitride has been grown” refers to a mode in which the first group III nitride and the second group III nitride are not grown continuously, that is, refers to a mode in which the first group III nitride is grown in the processing chamber of the depositing apparatus, and after being unloaded from the processing chamber, is loaded into the processing chamber of the same or another depositing apparatus, and the second group III nitride is regrown on the first group III nitride. After the first group III nitride is grown in the depositing apparatus, it is unloaded, for example, into the atmosphere, or, for example, into the atmosphere in a glove box. Before the second group III nitride is regrown, for example, the first group III nitride may be subjected to processing using various apparatuses.

When the first group III nitride, that is, the substrate 11, is unloaded from the depositing apparatus to the outside, the first group III nitride becomes contaminated. Thereby, impurities 14 such as Fe are adhered to the surface 13 of the first group III nitride (the surface 13 of the surface layer portion 12 of the substrate 11). In this embodiment, the impurities 14 refer to at least one impurity selected from the group consisting of Fe, Mg, chromium (Cr), and Si.

FIG. 1B is a schematic view showing the step of forming the protective layer 15 on the substrate 11. In the step of forming the protective layer 15, the substrate 11 is subjected to a predetermined oxidation treatment using an oxidation treatment device 150, and the outermost layer of the first group III nitride is converted into the protective layer 15 composed of the group III oxide. The oxidation treatment performed to form the protective layer 15 using the oxidation treatment device 150 will hereinafter be simply referred to as an oxidation treatment. As the oxidation treatment device 150, an appropriate device may be used depending on the specific content of the oxidation treatment. As described below, when, for example, a water vapor oxidation treatment is performed as the oxidation treatment, a water vapor oxidation treatment device is used, and when, for example, an anodizing treatment is performed, an anodizing treatment device is used.

The oxidation treatment is a treatment for changing the outermost layer of the first group III nitride, that is, a portion of the thickness of the surface side (shallow side) of the surface layer portion 12 of the substrate 11, into the group III oxide. After the oxidation treatment, the first group III nitride remains on the deeper side of the protective layer 15, which is the oxidized portion of the surface layer portion 12. Thereby, a surface 13a composed of the first group III nitride is formed as the interface of the substrate 11 in contact with the protective layer 15. In other words, the protective layer 15 is formed on the surface 13a. Due to the oxidation treatment, a nitride stack 16, which is an intermediate body of the nitride stack 100 and includes the substrate 11 and the protective layer 15, is formed.

In the oxidation treatment, the protective layer 15 is formed by oxidizing the surface layer portion 12 while the impurities 14 remain adhered to the surface 13. Thereby, the impurities 14 are disposed closer to the protective layer 15 than the surface 13a and are present integrally with the protective layer 15, that is, are included in the protective layer 15. The state in which the impurities 14 are present integrally with the protective layer 15 may be either a state in which the impurities 14 are present on the surface of the protective layer 15 or a state in which the impurities 14 are present inside of the protective layer 15.

The protective layer 15 is preferably formed so as to continuously cover the surface 13a of the first group III nitride. That is, the oxidation treatment is preferably continued until the surface 13a of the first group III nitride is continuously covered with the protective layer 15.

Further, the protective layer 15 preferably has a thickness of 2 nm or more, preferably 5 nm or more, and more preferably 40 nm or more. That is, it is preferable to continue the oxidation treatment until the thickness of the protective layer 15 reaches 2 nm or more, preferably 5 nm or more, and more preferably 40 nm or more.

It is considered that by taking out the substrate 11 from the depositing apparatus in which the first group III nitride has been grown, a very thin natural oxide film is formed on the surface of a surface layer portion 12. However, in this embodiment, the formation of a natural oxide film is not considered to be an oxidation treatment, and the natural oxide film is not considered to be the protective layer 15. This is because, as will be described later in comparative embodiments, the impurities 14 cannot be sufficiently removed by forming and removing the natural oxide film. In this embodiment, the oxidation treatment refers to a treatment for forming the protective layer 15 by actively oxidizing the surface of the surface portion 12 using an oxidation treatment device (a tool for oxidation treatment) 150 (rather than natural oxidation).

The oxidation treatment for forming the protective layer 15 is, for example, a water vapor oxidation treatment. In the water vapor oxidation treatment, water vapor is supplied as an oxidizing agent to the substrate 11 to oxidize the surface layer portion 12 of the first group III nitride. An example of the conditions for the water vapor oxidation treatment is as follows: N₂ gas is bubbled into H₂O heated to 96° C., and the N₂ gas containing water vapor is supplied into an annealing chamber. Then, in the above atmosphere, a heat treatment is performed at 950° C. to oxidize the surface of the first group III nitride (for example, GaN). The thickness of the obtained oxide film is, for example, about 3.2 nm after the treatment time of 20 minutes.

The oxidation treatment for forming the protective layer 15 may be, for example, anodizing treatment. Examples of the conditions for the anodizing treatment are as follows. A solution of propylene glycol and 3% tartaric acid mixed in a 2:1 ratio is used, and the pHis adjusted to 7.0 using sodium hydroxide. A potentiostat is used for the anodic oxidation, with Pt as a counter electrode and Ag/AgCl as a reference electrode. At a room temperature, a positive voltage is applied while irradiating the surface of the first group III nitride (eg, GaN) with UV light having a wavelength of 300 to 400 nm at an irradiation intensity of 4 mW/cm². The thickness of the obtained oxide film is, for example, about 100 nm after the treatment time of 20 minutes.

The protective layer 15 may be formed by other oxidation treatments. For example, the protective layer 15 may be formed by immersing the substrate 11 in high-concentration ozone water of 200 ppm or more for 10 minutes or more. Further, for example, the protective layer 15 may be formed by treating the substrate 11 with supercritical water at 30 MPa and 400° C. for 10 minutes or more.

FIG. 2A is a schematic view showing the step of removing the protective layer 15 from the substrate 11, and FIG. 2B is a schematic view showing the step of growing the film 21 on the substrate 11. The method for manufacturing the nitride stack 100 according to this embodiment is characterized in that a treatment for removing the protective layer 15 and a treatment for growing the film 21 are performed successively in a processing chamber 210 of the depositing apparatus 200 in which the film 21 is grown. That is, between the treatment of removing the protective layer 15 and the treatment of growing the film 21, the substrate 11 is not unloaded to outside of the processing chamber 210 but remains inside of the processing chamber 210.

The type of the depositing apparatus 200 is not particularly limited as long as it can perform the treatment described below. For example, a metal-organic vapor phase epitaxy (MOVPE) apparatus is used as the depositing apparatus 200. FIGS. 2A and 2B show schematic views of the depositing apparatus 200.

A susceptor 220 is provided in the processing chamber 210 of the depositing apparatus 200. The substrate 11 is placed on the susceptor 220. The susceptor 220 has a heater 230, which heats the substrate 11 to a predetermined processing temperature. A gas supply mechanism 240 supplies a processing gas 250 used for each treatment into the processing chamber 210.

The step of removing the protective layer 15 from the substrate 11 will be described with reference to FIG. 2A. The treatment of removing the protective layer 15 from the substrate 11 is performed by loading the substrate 11 (nitride stack 16) on which the protective layer 15 has been formed into the processing chamber 210 of the depositing apparatus 200 and heating it in a reducing atmosphere. The treatment is preferably performed, for example, in an atmosphere containing hydrogen (more specifically, for example, containing H₂ gas), or, for example, in an atmosphere containing ammonia in addition to hydrogen. The heating temperature is preferably set to, for example, 900° C. or higher and 1300° C. or lower. The heating time is preferably set to, for example, from 30 seconds to 30 minutes. The H₂ gas may be mixed with an inert gas such as N₂ gas or Ar gas and then supplied. By performing the treatment in an atmosphere containing ammonia, surface damage caused by thermal etching can be suppressed.

In this treatment, removal of the protective layer 15 is continued until an entire surface 13a of the substrate 11 is exposed, that is, until the first group III nitride that is present below the protective layer 15 is exposed. In this manner, the protective layer 15 is removed, and the impurities 14 are removed together with the protective layer 15.

The step of growing the film 21 on the substrate 11 will now be described, with reference to FIG. 2B. After the treatment of removing the protective layer 15 from the substrate 11, the step of growing the film 21 on the substrate 11 is performed by growing the second group III nitride on the surface 13a of the first group III nitride exposed by removing the protective layer 15, without unloading the substrate 11 from the processing chamber 210. In this manner, the nitride stack 100 having the substrate 11 and the film 21 is manufactured.

The second group III nitride constituting the film 21 is grown, for example, by MOVPE. Among the group III source gases, for example, trimethylaluminum (Al(CH₃)₃, TMA) gas is used as an aluminum (Al) source gas. Among the group III source gases, for example, trimethylgallium (Ga(CH₃)₃, TMG) gas is used as a gallium (Ga) source gas. Among the group III source gases, for example, trimethylindium (In(CH₃)₃, TMI) gas is used as an indium (In) source gas. For example, ammonia (NH₃) is used as a nitrogen (N) source gas, which is a group V source gas. For example, at least one of nitrogen gas (N₂ gas) and hydrogen gas (H₂ gas) is used as a carrier gas.

A growth temperature can be selected, for example, in a range of 700° C. to 1400° C., and the V/III ratio, which is the flow rate ratio of the group V source gas to the group III source gas, can be selected, for example, in a range of 10 to 5000. The ratio of the supply amounts of the source gases is adjusted depending on the composition of the film 21 to be formed.

Since the surface 13a of the first group III nitride is a surface from which the impurities 14 have been removed, the influence of reduced crystallinity caused by the impurities 14 is suppressed in the second group III nitride grown thereon. Therefore, the second III nitride, that is the film 21, does not have to be grown thick (eg, to a thickness of 4 μm or more). However, the film 21 may be grown thick (eg, to a thickness of 4 μm or more) as needed.

As a guideline indicating that the influence of the decrease in crystallinity caused by the impurities 14 is suppressed, the half-width of the (0002) diffraction is 300 arc seconds or less and the half-width of the (10-12) diffraction is 400 arc seconds or less in an X-ray rocking curve, for example, in a portion of the second group III nitride (i.e., film 21) within a thickness range of 4 μm from the interface with the first group III nitride film (i.e., from the surface 13a of the substrate 11).

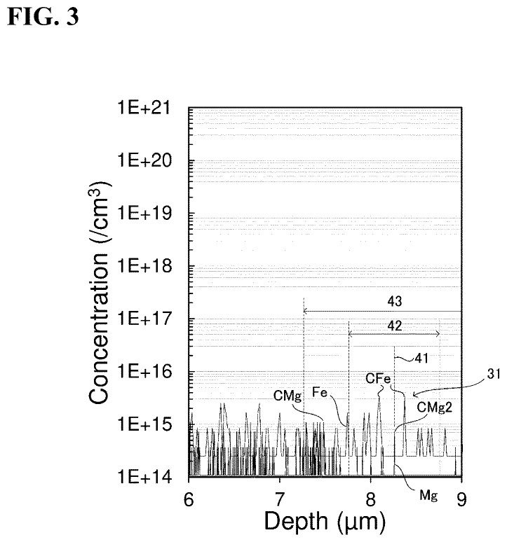

With reference to FIGS. 3 to 5, the characteristics of the impurity concentration distribution of the nitride stack 100 according to the embodiment will be described while comparing it with the characteristics of the impurity concentration distribution of the nitride stacks according to the first and second comparative embodiments. FIGS. 3, 4, and 5 are examples of SIMS profiles of the samples according to the embodiment, the first comparative embodiment, and the second comparative embodiment, respectively, showing the concentration distributions of Fe, Mg, and Cr.

The samples exemplified as the embodiment, the first comparative embodiment, and the second comparative embodiment are nitride stacks in which a GaN layer is epitaxially grown on a GaN substrate. In this example, the GaN constituting the GaN substrate is a first group III nitride, and the GaN constituting the GaN layer is a second group III nitride. Hereinafter, the interface between the GaN substrate and the GaN layer, that is, the interface between the first group III nitride and the second group III nitride, may be simply referred to as the interface. The interface in the embodiment can usually be easily distinguished by the difference in crystal composition or the difference in doping impurities between the first group III nitride and the second group III nitride, and can also be easily distinguished even when the first and second group III nitrides are both undoped GaN crystals or low-Si-doped crystals. Details of how the interfaces are defined in such an embodiment are described below.

The sample of the embodiment is fabricated by the following method: a GaN substrate exposed to the atmosphere is subjected to an oxidation treatment to form a gallium oxide layer as a protective layer on the GaN substrate, the GaN substrate with the protective layer formed thereon is loaded into the depositing apparatus, the protective layer is removed, and then the GaN layer is continuously grown.

The sample of the first comparative embodiment was fabricated by a method in which the GaN substrate exposed to the atmosphere was loaded into the depositing apparatus and the GaN layer was grown thereon without being subjected to the oxidation treatment as in the embodiment. The sample of the second comparative embodiment was fabricated by the following method: the GaN substrate exposed to the atmosphere was subjected to an acid cleaning treatment using a hydrofluoric acid solution without being subjected to an oxidation treatment, and then the substrate was loaded into the depositing apparatus and the GaN layer was grown thereon (that is, the acid cleaning treatment was added to the first comparative embodiment.). The acid cleaning treatment in the second comparative embodiment may be performed using a hydrochloric acid solution other than the hydrofluoric acid solution described above. Generally, the acid cleaning treatment is performed for 5 to 10 minutes, and then a water treatment is performed using running pure water for 5 to 10 minutes.

In the first and second comparative embodiments, before the GaN layer is grown, a heat treatment is performed in the depositing apparatus under a reducing atmosphere, thereby removing a natural oxide film on the GaN substrate. This is similar to the heat treatment in the reducing atmosphere for removing the protective layer in the embodiment. However, since the natural oxide film is very thin compared to the protective layer, the heat treatment time in the first and second comparative embodiments may be shorter than the heat treatment time in the embodiment. Specifically, in contrast to the heating time of 30 seconds or more (to remove the protective layer formed by oxidation treatment) in the embodiment, the heating time (to remove the natural oxide film) in the first and second comparative embodiments is sufficient with a heating time of, for example, 10 seconds or less (to remove the natural oxide film). In reality, the natural oxide film is sufficiently removed during the waiting period before growth, even without performing a heat treatment to remove the natural oxide film.

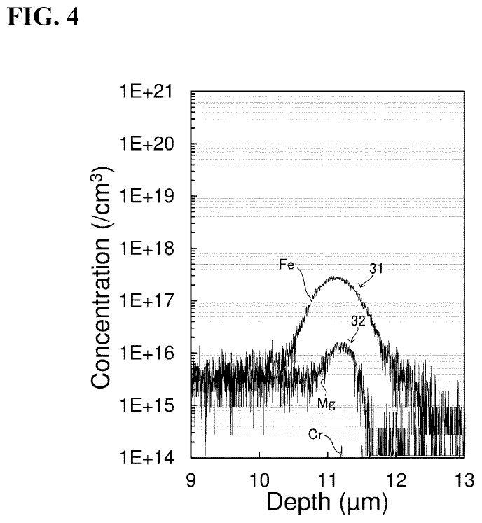

In the first comparative embodiment (FIG. 4), a protrusion 31 in the Fe concentration distribution and a protrusion 32 in the Mg concentration distribution are clearly observed near the stacking interface between the GaN substrate and the GaN layer. Further, a peak indicating the presence of Cr, although in a small amount, is observed near the stacking interface.

In the first comparative embodiment (FIG. 4), the formation of the natural oxide film due to exposure of the GaN substrate to the atmosphere and the removal of the natural oxide film prior to the growth of the GaN layer are carried out. However, impurities such as Fe are not sufficiently removed by the formation and removal of the natural oxide film.

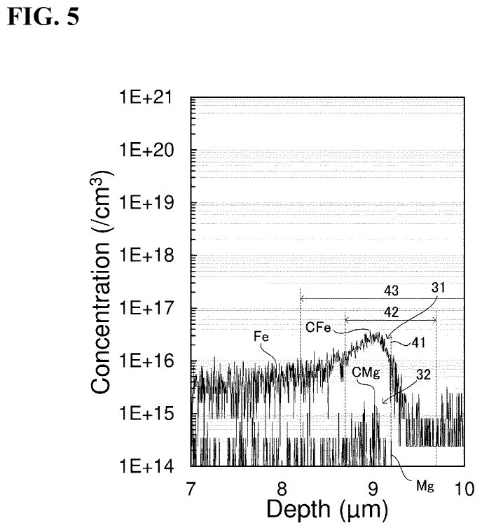

In the second comparative embodiment (FIG. 5), the concentrations of Fe and Mg are lower than those in the first comparative embodiment due to the acid cleaning treatment. The Cr concentration is below the lower detection limit of SIMS measurement (1×10¹⁴/cm³ or less). The Fe concentration in the second comparative embodiment is suppressed compared to the first comparative embodiment, but is still at such a high level that the shape of the protrusion 31 is still clearly visible. The Mg concentration in the second comparative embodiment is suppressed compared to the first comparative embodiment, and is at such a low level that the shape of the protrusion 32 is merely a trace.

In the embodiment (FIG. 3), the treatment of forming and removing the protective layer results in even lower concentrations of Fe and Mg than in the acid cleaning treatment of the second comparative embodiment. The Cr concentration is below the lower detection limit of SIMS measurement (1×10¹⁴/cm³ or less). The Fe concentration in this embodiment is further suppressed compared to the second comparative embodiment, and is at such a low level that the shape of the protrusion 31 is merely a trace. The Mg concentration in this embodiment is further suppressed compared to the second comparative embodiment, and is at such a low level that the protrusions 32 are not observed.

Here, the term “the protrusion is clear” means that the concentration distribution shape showing the protrusion, which is a portion where the impurity concentration is conspicuously high, is a curved shape. In an embodiment in which the level of the impurity concentration is high, it can be said that the concentration distribution shape showing the protrusion is a curved shape. In contrast, the term “the protrusion is merely a trace” means that the profile shape showing the protrusion is in an appearance of a discrete series of measurements above the detection limit. In an embodiment in which the impurity concentration is at such a low level close to a lower detection limit, it can be said that the concentration distribution shape showing the protrusion is merely a trace shape.

The first comparative embodiment shows a characteristic that the concentration level of Fe is higher than the concentration level of Mg. A similar tendency is observed in the second comparative embodiment and the embodiment. As for Fe, it is considered that the characteristic that the peak of the Fe concentration distribution exists near the stacking interface also remains in the second comparative embodiment and the embodiment because the Fe concentration level is relatively high and difficult to remove Fe. By applying the method of the embodiment, Fe may be removed to such an extent that there is no peak in the Fe concentration distribution near the stacking interface. As for Mg, the concentration level is relatively low and it is easier to remove Mg than Fe, so that the characteristic of the Mg concentration distribution having a peak near the stacking interface remains in the second comparative embodiment but does not remain in the embodiment.

Hereinafter, more detailed characteristic of the impurity concentration distribution near the stacked layer interface according to the embodiment will be described. In the first comparative embodiment (FIG. 4) also, the Mg concentration level on the GaN substrate side with respect to the protrusion 32 is low, on the order of 1×10¹⁴/cm³, that is, close to the lower detection limit. In the first comparative embodiment, the Mg concentration level on the GaN layer side of the protrusion 32 is high, on the order of 1×10¹⁵/cm³. In this manner, the Mg concentration distribution shape shows a step-like shape with respect to the protrusion 32, in which the concentration is relatively low on the GaN substrate side and relatively high on the GaN layer side.

In the second comparative embodiment (FIG. 5) which was subjected to the acid cleaning treatment, the Mg concentration distribution shape also has a step-like shape with a relatively low concentration on the GaN substrate side and a relatively high concentration on the GaN layer side with respect to the protrusion 32. However, in the second comparative embodiment, the Mg concentration level is further low on the GaN substrate side due to the acid cleaning treatment, and almost no measured values exceeding 1×10¹⁴/cm³ are observed. Further, on the GaN layer side, the Mg concentration is low, on the order of 1×10¹⁴/cm³.

Also in the embodiment in which the protective layer is formed and removed (FIG. 3), although no protrusion 32 is observed in the Mg concentration distribution, the step-like shape is similarly observed, in which the concentration is relatively low on the GaN substrate side and relatively high on the GaN layer side. The characteristic that almost no measured values exceeding 1×10¹⁴/cm³ were observed on the GaN substrate side and the Mg concentration on the GaN layer side was low on the order of 1×10¹⁴/cm³, is the same as the second comparative embodiment.

Regarding the evaluation of the concentration distribution in the second comparative embodiment and the embodiment, the interface between the GaN substrate and the GaN layer, that is, the interface between the first group III nitride and the second group III nitride, is defined as follows, in consideration of the step-like feature of the Mg concentration distribution near the stacking interface.

As for the Mg concentration, it can be said that the relatively low concentration region on the GaN substrate side is a region where the measured values exceeding 1×10¹⁴/cm³ are sparse. Here, the region where measured values exceeding 1×10¹⁴/cm³ are sparse is a region where there is no second measured value exceeding 1×10¹⁴/cm³ within a depth of 0.5 μm on the GaN substrate side from the first measured value exceeding 1×10¹⁴/cm³.

In contrast, as for the Mg concentration, it can be said that the relatively high concentration region on the GaN layer side is a region where the measured values exceeding 1×10¹⁴/cm³ are densely packed. Here, the region with dense measured values exceeding 1×10¹⁴/cm³ is a region where the second measured value exceeding 1×10¹⁴/cm³ is present within a depth of 0.5 μm on the GaN layer side from the first measured value exceeding 1×10¹⁴/cm³.

Such a depth position corresponding to the measured value of the Mg concentration, that is a boundary between the regions with sparse and dense measured values exceeding 1×10¹⁴/cm³, is defined as an interface 41. Further, a 1 μm thick range centered on the interface 41 is defined as an interface region 42, and a 2 μm thick range centered on the interface 41 is defined as a stacked region 43. The stacked region 43 indicates the stack of the GaN substrate and the GaN layer, and the interface region 42 indicates the region near the interface in the stack of the GaN substrate and the GaN layer.

“At the interface” means near the interface, i.e., within the interface region 42. The Fe concentration distribution having a peak at the interface is defined as such that the maximum value (peak concentration) CFe of the Fe concentration in the stacked region 43 is present within the interface region 42. Similarly, the Mg concentration distribution having a peak at the interface is defined as such that the maximum value (peak concentration) CMg of the Mg concentration in the stacked region 43 is present within the interface region 42.

In consideration of the above definition, the characteristic of the impurity concentration distribution in the sample shown in FIG. 5 as the second comparative embodiment and the characteristic of the impurity concentration distribution in the sample shown in FIG. 3 as the embodiment are compared as follows. The Fe concentration distribution in the second comparative embodiment has a peak at the interface, and the peak concentration CFe is about 4×10¹⁶/cm³. The Fe concentration distribution in the embodiment has a peak at the interface, and the peak concentration CFe is about 3×10¹⁵/cm³. The peak concentration CFe of Fe in the embodiment can be 2×10¹⁶/cm³ or less, preferably 1×10¹⁶/cm³ or less, and more preferably 5×10¹⁵/cm³ or less, which is lower than the peak concentration CFe of Fe in the second comparative embodiment.

The Mg concentration distribution in the second comparative embodiment has a peak at the interface, and the peak concentration CMg is about 3×10¹⁵/cm³. In the Mg concentration distribution of the embodiment, the maximum value CMg (approximately 1×10¹⁵/cm³) of the Mg concentration in the stacked region 43 is outside of the interface region 42, that is, there is no peak at the interface, and the maximum value CMg2 of the Mg concentration in the interface region 42 is about 7×10¹⁴/cm³. The maximum value CMg2 of the Mg concentration in the interface region 42 in the embodiment can be 2×10¹⁵/cm³ or less, preferably 1×10¹⁵/cm³ or less, which is lower than the maximum value CMg of the Mg concentration in the interface region 42 in the second comparative embodiment. In the embodiment, it can be said that Mg is removed to such an extent that the Mg concentration in the stacked region 43 is not significantly different between inside of the interface region 42 and outside of the interface region 42. Therefore, by applying the method of the embodiment, the maximum value CMg of the Mg concentration in the stacked region 43 may be outside of the interface region 42 (as in the example shown in FIG. 3) or may be within the interface region 42.

As described above, by applying the method of the embodiment, the (maximum) Cr concentration at the interface (within the interface region 42) can be reduced to below the lower detection limit (1×10¹⁴/cm³ or less).

Further, it has also been confirmed that by applying the method of the embodiment, the Si concentration at the interface (at the interface region 42) can be controlled as follows. When Si is not intentionally added to the first group III nitride and the second group III nitride, that is, when Si is an impurity adhered due to contamination, the (maximum) Si concentration at the interface (in the interface region 42) can be reduced to 1×10¹⁶/cm³ or less, preferably 1×10¹⁵/cm³ or less.

The method of the embodiment is also useful when Si is intentionally added to the first group III nitride and the second group III nitride (typically, when Si is added to each of the first and second group III nitrides at a concentration on the order of 1×10¹⁶/cm³). For example, as described above with reference to FIG. 7, in the conventional technique, the protrusion indicating a bias in the Si concentration distribution is observed at the stacking interface, and the maximum Si concentration at the protrusion is 1×10¹⁷/cm³ or more, which is a high value exceeding 10 times the added Si concentration.

When Si is intentionally added to the first group III nitride and the second group III nitride, the height of such a protrusion can be made lower than a conventional protrusion by applying the method of the embodiment. As a specific guideline, the Si concentration at the interface (maximum value of the Si concentration in interface region 42) can be 5 times or less, preferably 2 times or less, with respect to a higher one of the Si concentrations at positions 1 μm above and below the interface (interface 41) between the first group III nitride and the second group III nitride (at top and bottom ends of stacked region 43). Also, the (maximum) Si concentration at the interface (in the interface region 42) can be less than 1×10¹⁷/cm³.

As described above, according to this embodiment, the second group III nitride can be grown on the first group III nitride, in the state such that impurities (Fe, Mg, Cr, etc.,) adhering to the surface of the first group III nitride (due to contamination) are removed, and the bias in the concentration distribution of the impurities (Si, etc.,) added to the first group III nitride near the stacking interface is also suppressed.

The stacked structure of the first group III nitride and the second group III nitride to which the method of the present embodiment is applied may take various modes. The first and second group III nitrides may both be n-type (eg, in the mode of a vertical power device). The first and second group III nitrides may be p-type and n-type, or n-type and p-type respectively (in the mode of pn diode). Also, the first and second group III nitrides may both be p-type.

Also, the first and second group III nitrides may both be semi-insulating (eg, stacked up to a GaN channel in a GaN-on-GaN HEMT). The composition of the first group III nitride and the composition of the second group III nitride may be different, and for example, the first group III nitride may be GaN and the second group III nitride may be AlGaN (eg, in the mode of a HEMT in which an AlGaN layer is regrown).

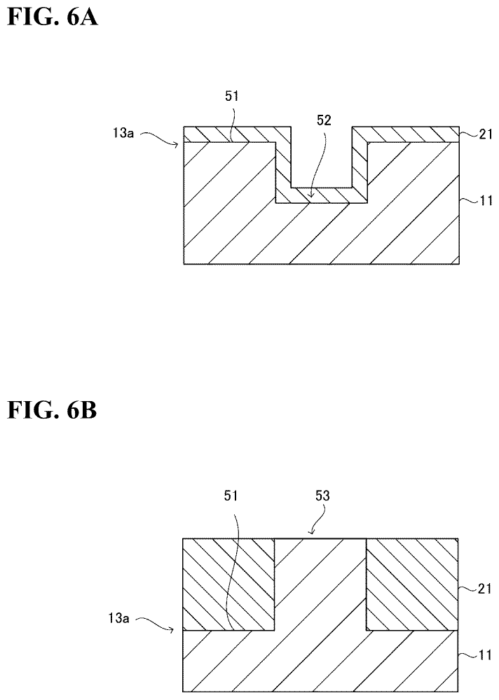

Also, the surface 13a of the first group III nitride (interface with the second group III nitride) does not necessarily have to be flat over an entire surface, and may have an uneven structure. FIG. 6A shows a first example of a mode in which the surface 13a of the first group III nitride has an uneven structure. The surface 13a in the first example has a main surface 51 and grooves 52. The main surface 51 in the first example is a surface that is inclined at an angle of 3 degrees or less from the C-plane of the first group III nitride crystal. The groove 52 in the first example has a side surface inclined from the main surface 51 by, for example, 30° to 90°. This example is an embodiment assuming, for example, a trench MOS, in which the first group III nitride is, for example, GaN, and the second group III nitride is, for example, AlGaN. In this example, after the first group III nitride is processed to form the grooves 52 (i.e., after the first group III nitride is taken out of the depositing apparatus), the second group III nitride is regrown. In response to such a regrowth, the second group III nitride is deposited at least on the side surface of the groove 52.

FIG. 6B shows a second example of an embodiment in which the surface 13a of the first group III nitride has an uneven structure. The surface 13a in the second example has a main surface 51 and a mesa structure 53. The main surface 51 in the second example is a surface that is inclined at an angle of 3 degrees or less from the C-plane of the first group III nitride crystal. The mesa structure 53 in the second example has a side surface that is inclined from the main surface 51 by, for example, 30° to 90°. This example shows an embodiment on the assumption of FINFET, for example, in which the first group III nitride is, for example, n-type GaN, and the second group III nitride is, for example, p-type GaN. In this example, after the first group III nitride is processed to form the mesa structure 53 (i.e., after the first group III nitride is taken out of the depositing apparatus), the second group III nitride is regrown. Corresponding to such regrowth, the second group III nitride is deposited at least on the side surface of the mesa structure 53.

In the structure shown in FIGS. 6A and 6B also, as described above, the concentration of various impurities at the stacking interface between the first group III nitride and the second group III nitride can be suitably controlled by the method of this embodiment. For example, the Fe concentration at the interface can be suppressed to 2×10¹⁶/cm³ or less.

As described above, in the method for manufacturing the nitride stack 100 according to an embodiment, the substrate 11 (first group III nitride) is prepared and taken out of the depositing apparatus, and a predetermined oxidation treatment is applied thereto using an oxidation treatment apparatus to form a protective layer 15. The protective layer 15 is then removed and a film 21 (second group III nitride) is grown continuously in a treatment chamber 210 in which the film 21 is grown.

Thereby, the concentration of impurities (Fe, Mg, Cr, Si, etc.) can be reduced on the surface 13a which is the interface (regrowth interface) between the first group III nitride and the second group III nitride. Further, thereby, even if the second group III nitride is not deposited thickly (even if the thickness is about 4 μm), the crystallinity of the second group III nitride can be good. Further, by reducing the concentrations of Fe and Mg at the regrowth interface, it is possible to avoid a decrease in the electrical conductivity of this portion, making it unnecessary to form a highly doped Si layer on the regrowth interface.

The oxidation treatment is performed while impurities 14 remain adhered to the surface 13 of the substrate 11. Thereby, the formation of the protective layer 15 does not need to be performed in situ after the formation of the first group III nitride but can be performed after the substrate 11 is taken out of the depositing apparatus. Further, in order to remove the impurities 14, it is not necessary to subject the substrate 11 to acid cleaning treatment, etc., after it has been taken out of the depositing apparatus.

The oxidation treatment is preferably continued until the surface 13a of the first group III nitride is continuously covered with the protective layer 15 (the entire surface 13a is covered with the protective layer 15). By forming the protective layer 15 as a continuous layer (a dense layer without pinholes), the impurities 14 can be removed without gaps on the surface 13a of the first group III nitride, together with the removal of the protective layer 15.

The oxidation treatment is preferably continued until the thickness of the protective layer 15 reaches 2 nm or more, preferably 5 nm or more, more preferably 40 nm or more. By setting the thickness of the protective layer to 15 to 2 nm or more, the protective layer 15 with few pinholes can be realized, and the impurities 14 can be effectively removed together with the removal of the protective layer 15. Further, by setting the thickness of the protective layer 15 to 40 nm or more, the pinholes can be completely eliminated, and a residual impurity concentration at the interface can be more reliably reduced to approximately the background level of SIMS. There is no particular upper limit to the thickness of the protective layer 15, but if it is too thick, it will take a long time to form and remove it, which may result in a decrease in productivity of the nitride stack 100 and an increase in a manufacturing cost. Therefore, it is desirable that the thickness of the protective layer 15 is, for example, 300 nm or less, and preferably 150 nm or less.

In this embodiment, the substrate 11 may be an epitaxial substrate in which the first group III nitride is epitaxially grown on a heterogeneous substrate (not composed of the group III nitride) (this is referred to as a former embodiment). However, as the substrate 11, it is preferable to use a free-standing substrate whose entire thickness is composed of the first group III nitride, or an epitaxial substrate in which the first group III nitride is grown on the free-standing substrate (homogeneous substrate) composed of the group III nitride (that is, the substrate 11 includes the free-standing substrate composed of the group III nitride (this is referred to as a latter embodiment).) This is because it has been found that in the latter embodiment, the oxide film (protective layer 15) formed by the oxidation treatment is denser and has a flatter surface than in the former embodiment.

The oxidation treatment is performed, for example, by using a technique of water vapor oxidation, or, for example, by using a technique of anodization. By performing the oxidation treatment using these techniques, the protective layer 15 can be formed into a continuous layer having the above-described thickness. As a result, the above-described effect can be obtained more reliably.

Due to the oxidation treatment, a nitride stack 16 is formed, which is an intermediate body of the nitride stack 100 and includes the substrate 11 and the protective layer 15. Due to the protective layer 15 being formed on the surface 13a of the first group III nitride, even if the nitride stack (intermediate body) 16 is exposed to the atmosphere or is stored or distributed in a resin container for a long period of time, further deposition of the impurities on the surface 13a of the first group III nitride, can be avoided.

Further, the protective layer 15 is composed of a group III oxide, which has a lower etching resistance than a group III nitride, and therefore can be easily removed in a gas phase. Therefore, by removing the protective layer 15 in the processing chamber 210 in which the film 21 composed of the second group III nitride is grown, and then continuously forming the film 21 composed of the second group III nitride, the contamination of the surface 13a, which is the interface (regrowth interface) between the first group III nitride and the second group III nitride, can be prevented and the impurity concentration can be reduced.

In the process of removing the protective layer 15, removal of the protective layer 15 is continued until the surface 13a of the substrate 11 is exposed, that is, until the group III nitride is exposed, which is present below the protective layer 15 in the first group III nitride. The protective layer 15 contains the impurities 14. By continuing the removal (thermal etching) of the protective layer 15 until the surface 13a is exposed, the impurities 14 can be removed together with the protective layer 15 from the surface 13a of the first group III nitride. As a result, the above-described effect can be obtained more reliably.

After the removal of the protective layer 15, the nitride stack 100 including the substrate 11 and the film 21 is manufactured by growing the film 21 on the substrate 11. The Fe concentration distribution at the interface between the substrate 11 and the film 21, that is, the interface between the first group III nitride and the second group III nitride, typically has a peak at the interface, and a peak concentration is 2×10¹⁶/cm³ or less, preferably 1×10¹⁶/cm³ or less, and more preferably 5×10¹⁵/cm³ or less. Further, the maximum value of the Mg concentration at the interface is 2×10¹⁵/cm³ or less, preferably 1×10¹⁵/cm³ or less.

In the nitride stack 100, due to a low impurity concentration (contamination is suppressed) on the surface 13a of the substrate 11 that serves as the base for the film 21, that is, a regrowth interface, the crystallinity becomes good even when the second group III nitride constituting the film 21 is not grown thick (for example, to a thickness of about 4 μm or less). Further, by reducing the concentrations of Fe and Mg at the regrowth interface, a decrease in electrical conductivity at this portion can be avoided, and a highly doped Si layer is not required to be formed on the regrowth interface.

### Preferable embodiment of the Present Disclosure

Preferable embodiments of the present disclosure will be described below.

### Supplementary Description 1

A method for manufacturing a nitride stack, including:
(a) preparing a substrate having at least a surface layer portion composed of a first group III nitride, the substrate being unloaded from a depositing apparatus in which the first group III nitride is grown;
(b) subjecting the substrate to a predetermined oxidation treatment using an oxidation treatment device to convert an outermost layer of the first group III nitride into a protective layer composed of a group III oxide;
(c) loading the substrate into a predetermined processing chamber and heating the substrate in a reducing atmosphere to remove the protective layer from a surface of the substrate; and
(d) growing a second group III nitride on a surface of the first group III nitride exposed by removing the protective layer, without unloading the substrate from the processing chamber.

### Supplementary Description 2

The method for manufacturing a nitride stack according to supplementary description 1, wherein in the step (b), the surface layer portion of the first group III nitride is oxidized while at least one impurity selected from a group consisting of Fe, Mg, Cr, and Si remains adhered to the surface of the first group III nitride.

### Supplementary Description 3

The method for manufacturing a nitride stack according to supplementary description 1, wherein in the step (b), the oxidation treatment is continued until the surface of the first group III nitride is continuously covered with the protective layer.

### Supplementary Description 4

The method for manufacturing a nitride stack according to supplementary description 1, wherein in the step (b), the oxidation treatment is continued until a thickness of the protective layer reaches 2 nm or more (preferably 5 nm or more, more preferably 40 nm or more).

### Supplementary Description 5

The method for manufacturing a nitride stack according to supplementary description 1, wherein in the step (b), water vapor is supplied to the substrate as an oxidizing agent to oxidize the surface layer portion of the first group III nitride.

### Supplementary Description 6

The method for manufacturing a nitride stack according to supplementary description 1, wherein in the step (b), the surface layer portion of the first group III nitride is oxidized by a technique of anodization.

### Supplementary Description 7

The method for manufacturing a nitride stack according to supplementary description 1, wherein in the step (c), the removal of the protective layer is continued until the first group III nitride that is present below the protective layer is exposed.

### Supplementary Description 8

The method for manufacturing a nitride stack according to supplementary description 1, wherein in the step (c), the impurities adhered to the surface of the first group III nitride are removed together with the protective layer.

### Supplementary Description 9

The method for manufacturing a nitride stack according to supplementary description 1, wherein in the step (c), the protective layer is removed from the surface of the substrate by heating the substrate to a temperature of 900° C. or higher in a hydrogen-containing atmosphere in a processing chamber of a depositing apparatus in which the second group III nitride is grown.

### Supplementary Description 10

The method for manufacturing a nitride stack according to supplementary description 1, wherein in the step (c), the protective layer is removed from the surface of the substrate by heating the substrate to a temperature of 900° C. or higher in an atmosphere containing hydrogen and ammonia in a processing chamber of a depositing apparatus in which the second group III nitride is grown.

### Supplementary Description 11

The method for manufacturing a nitride stack according to any one of the supplementary descriptions 1 to 10, wherein the first and second group III nitrides are both n-type.

### Supplementary Description 12

The method for manufacturing a nitride stack according to any one of the supplementary descriptions 1 to 10, wherein the first and second group III nitrides are both semi-insulating.

### Supplementary Description 13

The method for manufacturing a nitride stack according to any one of the supplementary descriptions 1 to 10, wherein the first group III nitride is GaN and the second group III nitride is AlGaN.

### Supplementary Description 14

The method for manufacturing a nitride stack according to any one of the supplementary descriptions 1 to 10, wherein the first and second group III nitrides are p-type and n-type, or n-type and p-type, respectively.

### Supplementary Description 15

The method for manufacturing a nitride stack according to any one of the supplementary descriptions 1 to 10, wherein the first group III nitride is GaN, the surface of the first group III nitride has a main surface inclined at 3° or less from a C-plane and a groove having a side surface inclined at 30° to 90° from the main surface, and the second group III nitride is AlGaN.

### Supplementary Description 16

The method for manufacturing a nitride stack according to any one of the supplementary descriptions 1 to 10, wherein the first group III nitride is n-type GaN, the surface of the first group III nitride has a mesa structure having a main surface inclined at 3° or less from the C-plane and a side surface inclined at an angle of 30° to 90° from the main surface, and the second group III nitride is p-type GaN.

### Supplementary Description 17

A nitride stack including:
a substrate having at least a surface portion composed of a first group III nitride; and
a protective layer composed of a group III oxide provided on a surface of the first group III nitride.

### Supplementary Description 18

The nitride stack according to supplementary description 17, wherein the protective layer is provided so as to continuously cover the surface of the first group III nitride.

### Supplementary Description 19

The nitride stack according to the supplementary description 17, wherein the protective layer has a thickness of 2 nm or more (preferably 5 nm or more, more preferably 40 nm or more).

### Supplementary Description 20

The nitride stack according to any one of the supplementary descriptions 17 to 20, wherein the protective layer contains at least one impurity selected from a group consisting of Fe, Mg, Cr, and Si.

### Supplementary Description 21

A nitride stack including:
a substrate having at least a surface portion composed of a first group III nitride; and
a protective layer composed of a group III oxide provided on a surface of the first group III nitride,
wherein a concentration distribution of Fe at an interface between the first group III nitride and the second group III nitride has a peak at the interface, and a peak concentration is 2×10¹⁶/cm³ or less (preferably 1×10¹⁶/cm³ or less, and more preferably 5×10¹⁵/cm³ or less).

### Supplementary Description 22

The nitride stack according to the supplementary description 21, wherein a Mg concentration at the interface between the first group III nitride and the second group III nitride is 2×10¹⁶/cm³ or less (preferably 1×10¹⁶/cm³ or less).

### Supplementary Description 23

The nitride stack according to the supplementary description 21, wherein a Cr concentration at the interface between the first group III nitride and the second group III nitride is 1×10¹⁴/cm³ or less.

### Supplementary Description 24

The nitride stack according to the supplementary description 21, wherein a Si concentration at the interface between the first group III nitride and the second group III nitride is 1×10¹⁶/cm³ or less (preferably 1×10¹⁵/cm³ or less).

### Supplementary Description 25

The nitride stack according to the supplementary description 21, wherein a Si concentration at the interface between the first group III nitride and the second group III nitride is 5 times or less (preferably 2 times or less) with respect to a higher one of Si concentrations at positions 1 μm above and below the interface between the first group III nitride and the second group III nitride.

### Supplementary Description 26

The nitride stack according to any one of the supplementary descriptions 21 to 25, wherein at a portion of the second group III nitride within a thickness range of 4 μm from the interface with the first group III nitride, a half width of (0002) diffraction is 300 seconds or less and a half width of (10-12) diffraction is 400 seconds or less in an X-ray rocking curve.

### Supplementary Description 27

A nitride stack including:
a substrate having at least a surface portion composed of a first group III nitride; and
a film composed of a second group III nitride provided on a surface of the first group III nitride,
wherein the first group III nitride is GaN, and a surface of the first group III nitride has a main surface inclined at an angle of 3° or less from a C-plane and a groove having a side surface inclined at an angle of 30° to 90° from the main surface, and
the second III-nitride is AlGaN, and the second III-nitride is provided on at least the side surface of the groove in the first III-nitride, and
a Fe concentration at the interface between the first group III nitride and the second group III nitride is 2×10¹⁶/cm³ or less.

### Supplementary Description 28

A nitride stack including:
a substrate having at least a surface portion composed of a first group III nitride; and
a film composed of a second group III nitride provided on a surface of the first group III nitride,
wherein the first group III nitride is n-type GaN, and a surface of the first group III nitride has a mesa structure having a main surface inclined at an angle of 3° or less from a C-plane and a side surface inclined at an angle of 30° to 90° from the main surface, and
the second III-nitride is p-type GaN, and the second III-nitride is provided on at least the side surface of the mesa structure of the first III-nitride, and
a Fe concentration at an interface between the first group III nitride and the second group III nitride is 2×10¹⁶/cm³ or less.

What is claimed is:

1. A method for manufacturing a nitride stack, comprising:
(a) preparing a substrate having at least a surface layer portion composed of a first group III nitride, the substrate being unloaded from a depositing apparatus in which the first group III nitride has been grown;
(b) subjecting the substrate to a predetermined oxidation treatment using an oxidation treatment device to convert an outermost layer of the first group III nitride into a protective layer composed of a group III oxide;
(c) loading the substrate into a predetermined processing chamber and heating the substrate in a reducing atmosphere to remove the protective layer from a surface of the substrate; and
(d) growing a second group III nitride on a surface of the first group III nitride exposed by removing the protective layer, without unloading the substrate from the processing chamber.

2. The method for manufacturing a nitride stack according to claim 1, wherein in the step (b), the surface layer portion of the first group III nitride is oxidized while at least one impurity selected from a group consisting of Fe, Mg, Cr, and Si remains adhered to the surface of the first group III nitride.

3. The method for manufacturing a nitride stack according to claim 1, wherein in the step (b), the oxidation treatment is continued until the surface of the first group III nitride is continuously covered with the protective layer.

4. The method for manufacturing a nitride stack according to claim 1, wherein in the step (b), the oxidation treatment is continued until a thickness of the protective layer reaches 2 nm or more.

5. The method for manufacturing a nitride stack according to claim 1, wherein in the step (b), water vapor is supplied to the substrate as an oxidizing agent to oxidize the surface layer portion of the first group III nitride.

6. The method for manufacturing a nitride stack according to claim 1, wherein in the step (b), the surface layer portion of the first group III nitride is oxidized by a technique of anodization.

7. The method for manufacturing a nitride stack according to claim 1, wherein in the step (c), the removal of the protective layer is continued until the first group III nitride that is present below the protective layer is exposed.

8. The method for manufacturing a nitride stack according to claim 1, wherein in the step (c), the impurities adhered to the surface of the first group III nitride are removed together with the protective layer.

9. The method for manufacturing a nitride stack according to claim 1, wherein in the step (c), the protective layer is removed from the surface of the substrate by heating the substrate to a temperature of 900° C. or higher in a hydrogen-containing atmosphere in a processing chamber of a depositing apparatus in which the second group III nitride is grown.

10. The method for manufacturing a nitride stack according to claim 1, wherein in the step (c), the protective layer is removed from the surface of the substrate by heating the substrate to a temperature of 900° C. or higher in an atmosphere containing hydrogen and ammonia in a processing chamber of a depositing apparatus in which the second group III nitride is grown.

11. A nitride stack comprising:
a substrate having at least a surface portion composed of a first group III nitride; and
a protective layer composed of a group III oxide provided on a surface of the first group III nitride.

12. The nitride stack according to claim 11, wherein the protective layer is provided so as to continuously cover the surface of the first group III nitride.

13. The nitride stack according to claim 11, wherein the protective layer has a thickness of 2 nm or more.

14. The nitride stack according to claim 11, wherein the protective layer contains at least one impurity selected from a group consisting of Fe, Mg, Cr, and Si.

15. A nitride stack comprising:
a substrate having at least a surface portion composed of a first group III nitride; and
a film composed of a second group III nitride provided on a surface of the first group III nitride,
wherein a Fe concentration distribution at an interface between the first group III nitride and the second group III nitride has a peak at the interface, and a peak concentration is 2×10¹⁶/cm³ or less.

16. The nitride stack according to claim 15, wherein a Mg concentration at the interface between the first group III nitride and the second group III nitride is 2×10¹⁵/cm³ or less.

17. The nitride stack according to claim 15, wherein a Cr concentration at the interface between the first group III nitride and the second group III nitride is 1×10¹⁴/cm³ or less.

18. The nitride stack according to claim 15, wherein a Si concentration at the interface between the first group III nitride and the second group III nitride is 1×10¹⁶/cm³ or less.

19. The nitride stack according to claim 15, wherein a Si concentration at the interface between the first group III nitride and the second group III nitride is 5 times or less with respect to a higher one of Si concentrations at positions 1 μm above and below the interface between the first group III nitride and the second group III nitride.

20. The nitride stack according to claim 15, wherein at a portion of the second group III nitride within a thickness range of 4 μm from the interface with the first group III nitride, a half width of (0002) diffraction is 300 seconds or less and a half width of (10-12) diffraction is 400 seconds or less in an X-ray rocking curve.
